(19) United States
(12) Patent Application Publication
(10) Pub. No.: US 2025/0240982 A1
(43) Pub. Date: Jul. 24, 2025

(54) THIN FILM RESISTOR AND METHODS OF FORMING THE SAME

(71) Applicant: Taiwan Semiconductor Manufacturing Company, Ltd., Hsinchu (TW)

(72) Inventors: Yu-Chi CHANG, Hsinchu (TW); Hsin-Li CHENG, Hsinchu (TW); Tuo-Hsin CHIEN, Hsinchu (TW)

(21) Appl. No.: 18/416,800

(22) Filed: Jan. 18, 2024

(51) Int. Cl. H01C 17/08; H01C 7/00; H01L 23/522

(52) U.S. Cl. CPC H10D 1/474; H01C 7/006; H01C 17/08; H01L 23/5228

(57) ABSTRACT

Some implementations described herein include a semiconductor device including a thin film resistor structure and techniques for forming the thin film resistor structure. Techniques described herein include forming a layer of a resistive material using a dual-component physical vapor deposition process and forming contact structures on the layer of resistive material by directly patterning a layer of conductive material on the layer of the resistive material. The techniques further include oxidizing a surface of the layer of the resistive material between the contact structures.

### BACKGROUND

Semiconductor-based integrated circuits may include a wide range of semiconductor devices. These semiconductor devices may include active semiconductor devices and/or passive semiconductor devices. Active semiconductor devices may include transistors and other semiconductor devices that operate using a power source. Passive semiconductor devices include inductors, capacitors, resistors, and/or other semiconductor devices that can operate without a power source. Resistors are widely used in many applications, such as resistor-capacitor circuits, power drivers, power amplifiers, and/or radio frequency applications, among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example semiconductor device described herein.

FIGS. 3A-3K are diagrams of an example series of semiconductor manufacturing operations used to form a thin film resistor structure described herein.

FIG. 4 is a diagram of example data related to a thin film resistor structure described herein.

FIG. 5 is a diagram of example components of a device associated with forming a thin film resistor structure described herein.

FIG. 6 is a flowchart of an example process associated with forming a thin film resistor structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A resistor structure, such as a thin film resistor (TFR) structure, may be formed in a semiconductor device. For an application in which the semiconductor device is exposed to an extreme temperature range, a near-zero temperature coefficient of resistance (TCR) may be desirable for the thin film resistor structure so that a performance of the thin film resistor structure (e.g., a resistance or an impedance) remains consistent across the extreme temperature range. Furthermore, a high sheet resistance (Rₛ) may be desirable such that integrated circuitry including the thin film resistor structure is compatible with an available power source.

In some cases, the semiconductor device includes a passivation layer over a resistive layer of the thin film resistor structure. In such cases, the resistive layer may be formed using a multi-layer sputtering operation. Furthermore, and in such cases, the passivation layer may necessitate masking and etching operations to form contact structures (e.g., metal landings) on the resistive layer. The use of the multi-layer sputtering operation in combination with the masking and etching operations may consume significant resources (e.g., labor, semiconductor processing tools, raw materials, and or computing resources) to fabricate the thin film resistor structure. Furthermore, and in such cases, the thin film resistor structure may fail to satisfy a TCR performance threshold and/or an Rₛ threshold that enables functionality of integrated circuitry including the thin film resistor structure across a temperature range and/or for an available power source associated with a given application.

Some implementations described herein include a semiconductor device including a thin film resistor structure and techniques for forming the thin film resistor structure. Techniques described herein include forming a layer of a resistive material using a dual-component physical vapor deposition process and forming contact structures on the layer of resistive material by directly patterning a layer of conductive material on the layer of the resistive material. The techniques further include oxidizing a surface of the layer of the resistive material between the contact structures.

In this way, an amount of semiconductor processing steps to form the thin film resistor structure is reduced. Furthermore, a TCR performance and an Rₛ performance of the thin film resistor structure is improved. By reducing the amount of semiconductor processing steps, improving the TCR performance, and improving the Rₛ performance, an amount of resources required to produce semiconductor devices using the thin film resistor structure (e.g., semiconductor processing tools, labor, raw material, and/or computing resources) may be reduced relative to other semiconductor devices using other thin film resistor structures formed using other techniques.

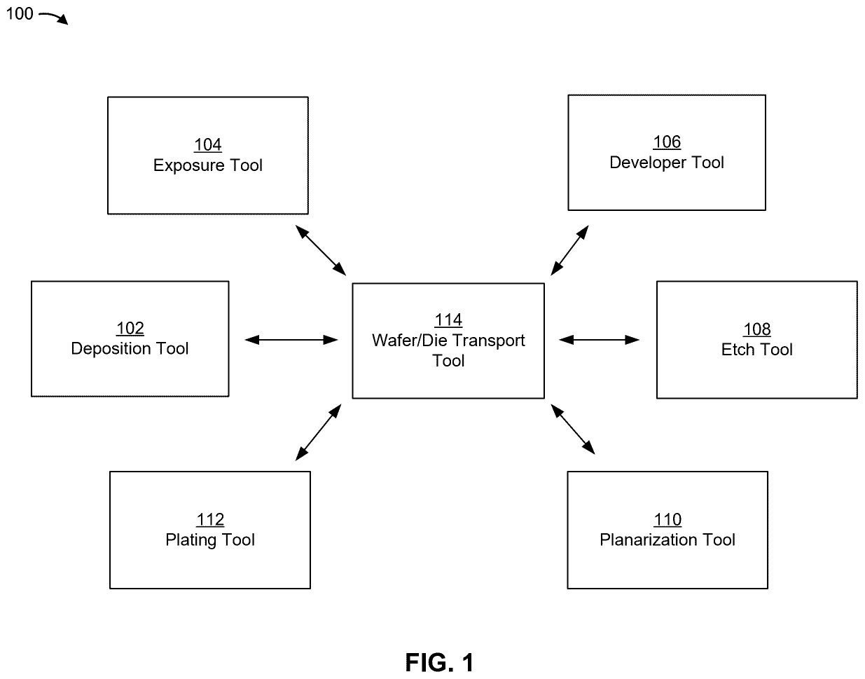

FIG. 1 is a diagram of an example environment 100 in which systems and/or methods described herein may be implemented. As shown in FIG. 1, the example environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 may be used to develop a pattern by removing unexposed portions of a photoresist layer. In some implementations, the developer tool 106 may be used to develop a pattern by removing exposed portions of a photoresist layer. In some implementations, the developer tool 106 may be used to develop a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

Wafer/die transport tool 114 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 may be a programmed device that is configured to travel a particular path and/or may operate semi-autonomously or autonomously. In some implementations, the example environment 100 includes a plurality of wafer/die transport tools 114.

For example, the wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

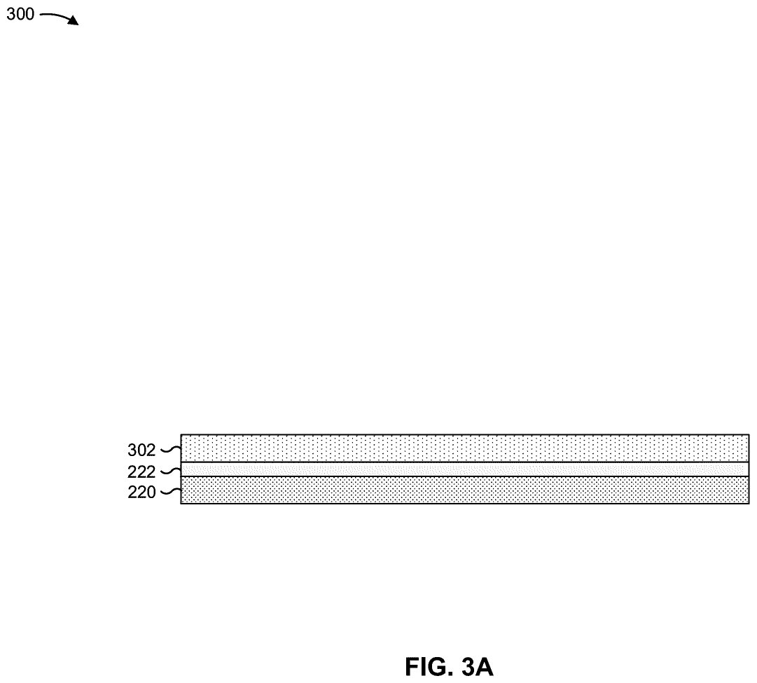

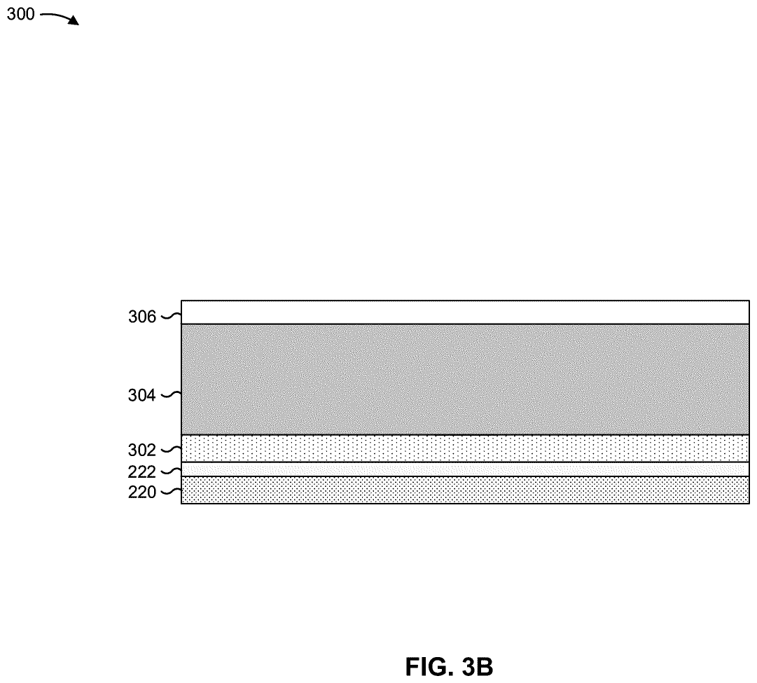

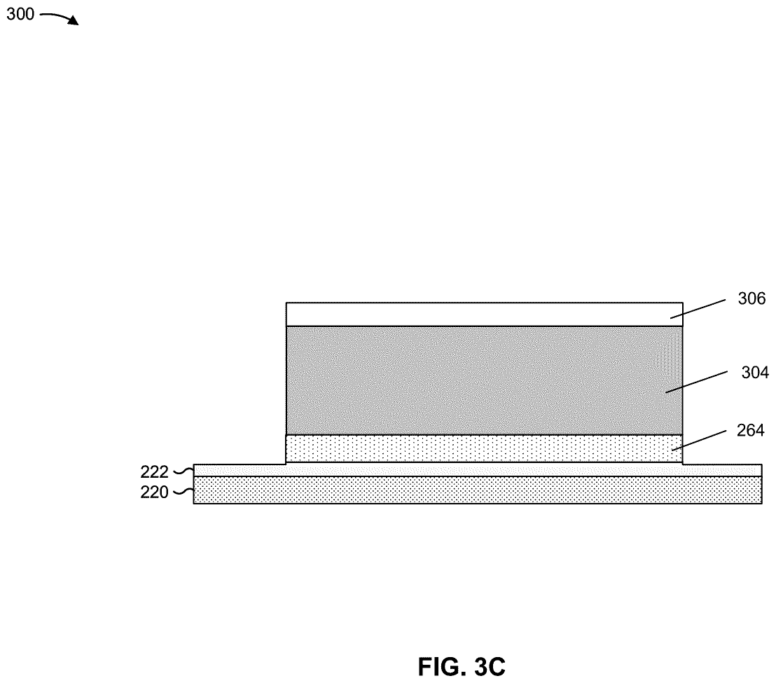

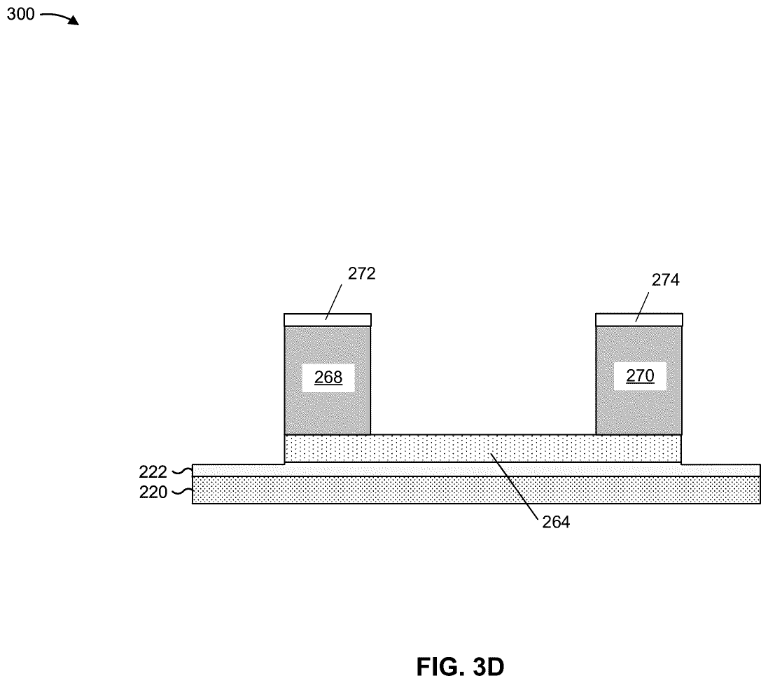

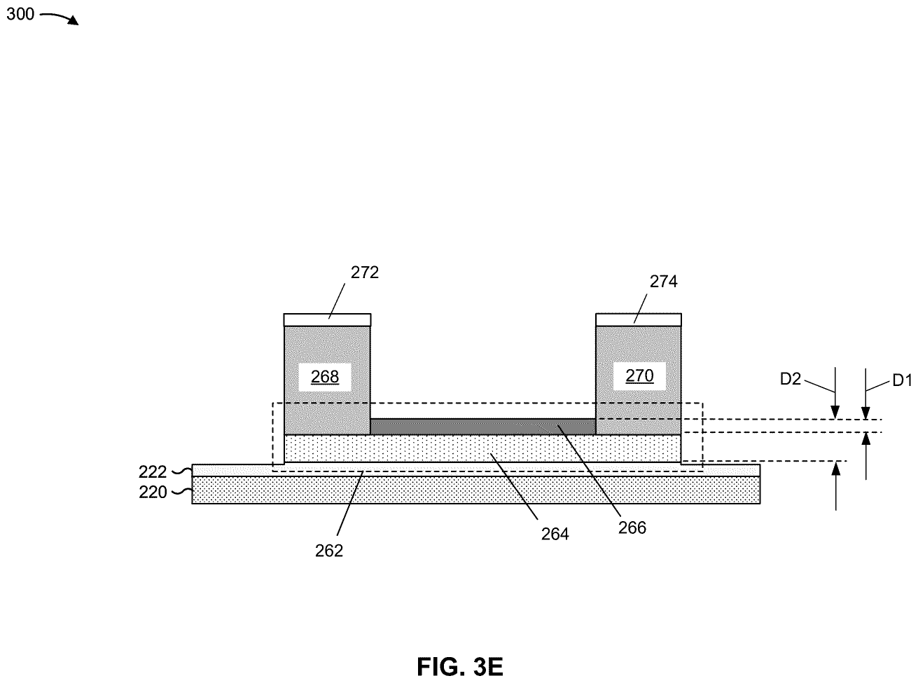

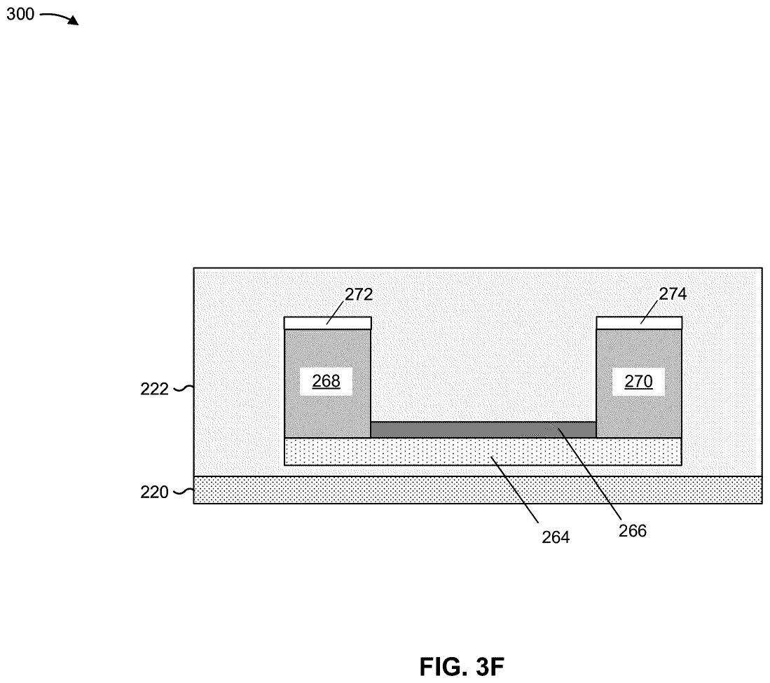

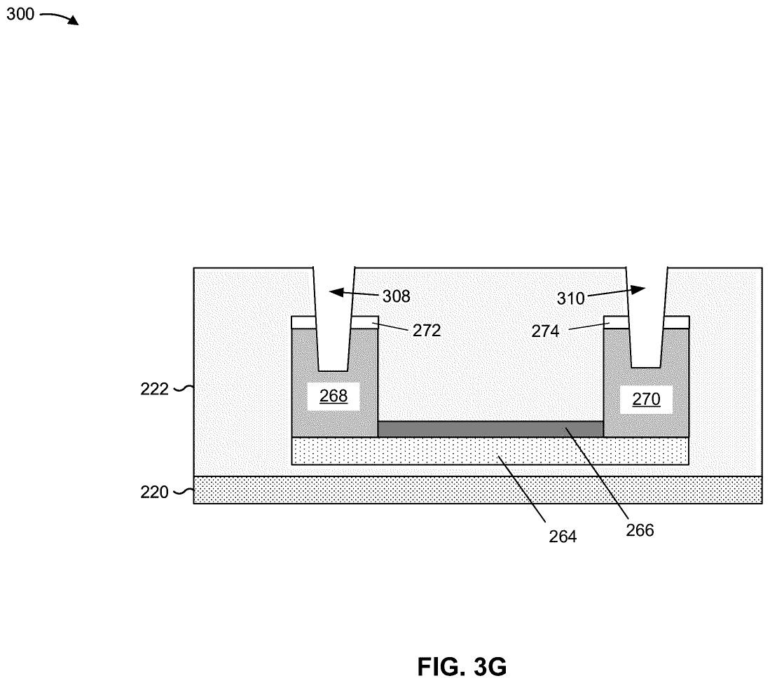

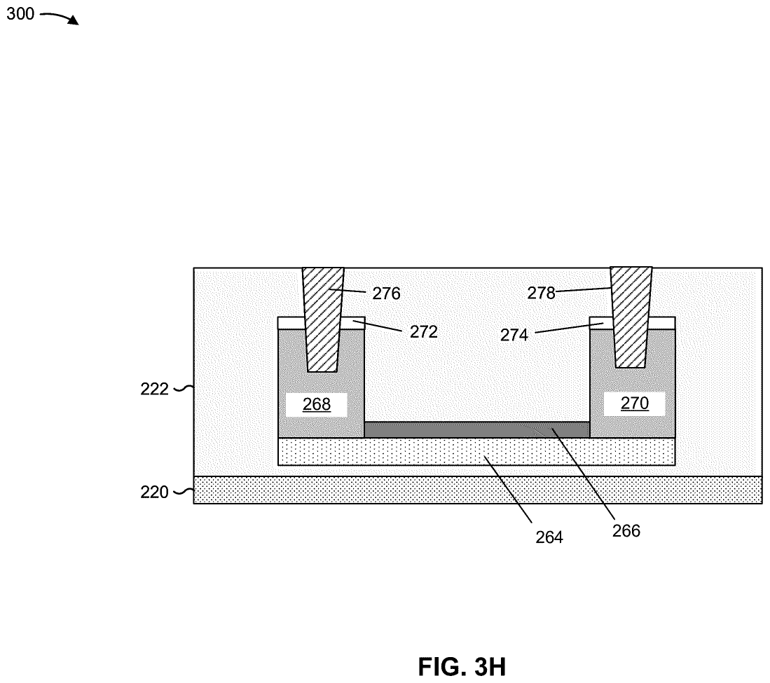

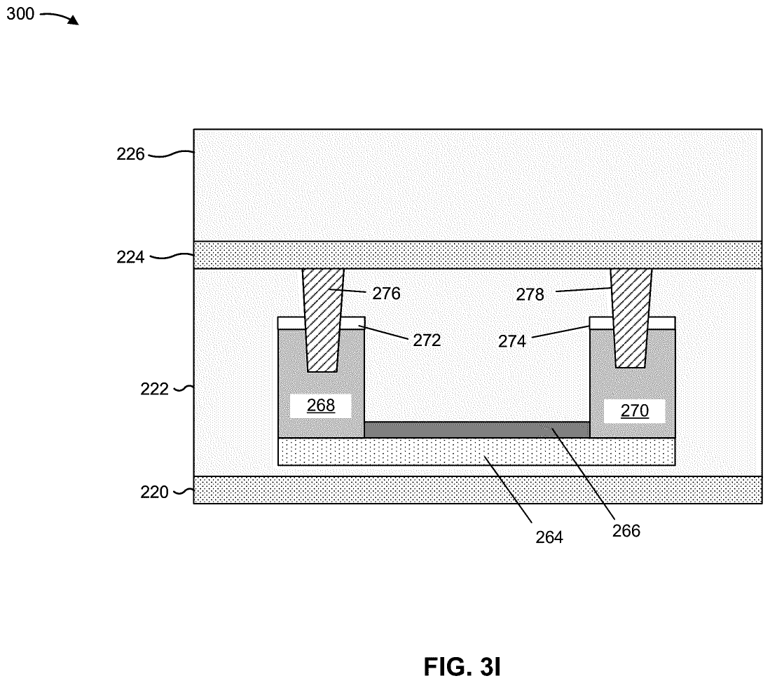

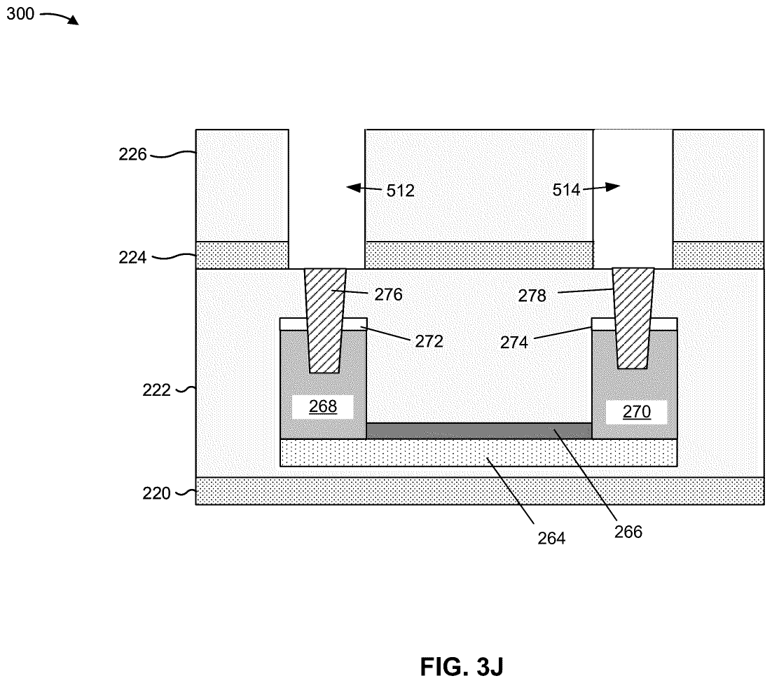

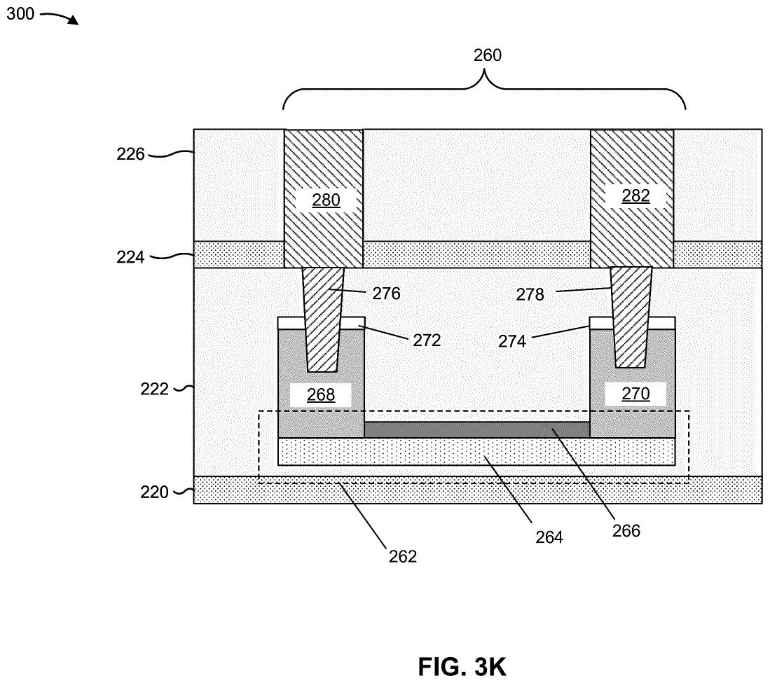

In some implementations, one or more of the semiconductor processing tools 102-112 and/or the wafer/die transport tool 114 may perform a series of semiconductor processing operations that form a thin film resistor structure described herein. For example, the series of semiconductor processing operations includes forming a resistive layer. The series of semiconductor processing operations includes forming a conductive layer on the resistive layer. The series of semiconductor processing operations includes forming a first portion of a multi-layer resistive body using the resistive layer. The series of semiconductor processing operations includes forming first and second contact structures on opposite ends of the first portion using the conductive layer. The series of semiconductor processing operations includes forming a second portion of the multi-layer resistive body by oxidizing a surface of the first portion between the first and second contact structures. In some implementations, one or more of the semiconductor processing tools 102-112 and/or the wafer/die transport tool 114 may perform one or more operations described in connection with FIGS. 3A-3K, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

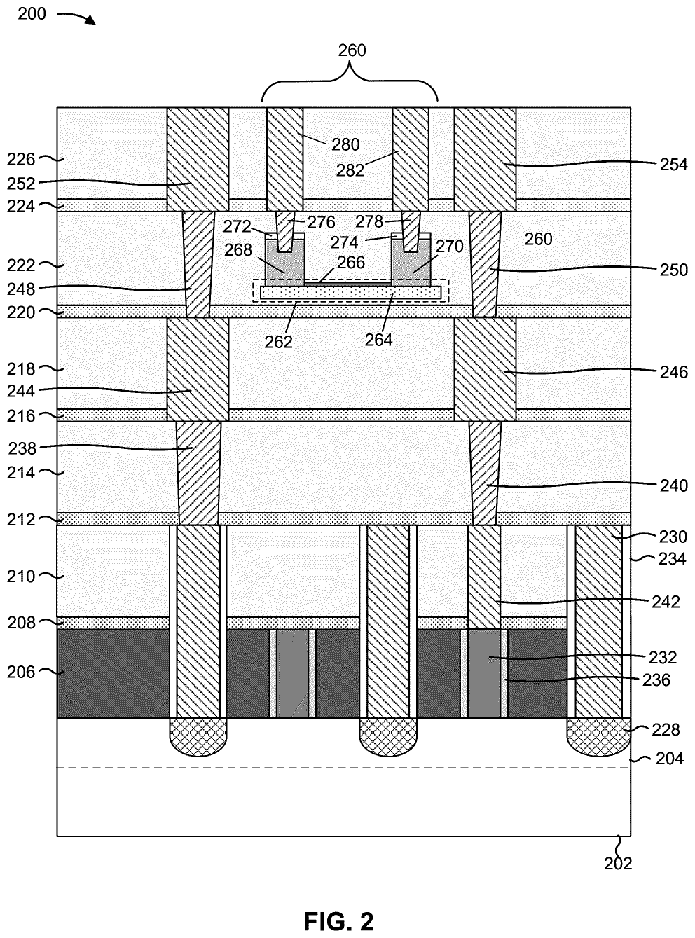

FIG. 2 is a diagram of a portion of an example semiconductor device 200 described herein. The semiconductor device 200 includes an example of a semiconductor device, such as a semiconductor memory device (e.g., a static random access memory (SRAM), a dynamic random access memory (DRAM), a semiconductor logic device, a processor, an input/output device, or another type of semiconductor device that includes one or more transistors.

The semiconductor device 200 includes a substrate 202 (e.g., a silicon substrate) and one or more fin structures 204. The semiconductor device 200 further includes one or more stacked layers, including a dielectric layer 206, an etch stop layer (ESL) 208, a dielectric layer 210, an ESL 212, a dielectric layer 214, an ESL 216, a dielectric layer 218, an ESL 220, a dielectric layer 222, an ESL 224, and a dielectric layer 226, among other examples. The dielectric layers 206, 210, 214, 218, 222, and 226 are included to electrically isolate various structures of the semiconductor device 200. The dielectric layers 206, 210, 214, 218, 222, and 226 include a silicon nitride (SiNₓ), an oxide (e.g., a silicon oxide (SiOₓ) and/or another oxide material), and/or another type of dielectric material. The ESLs 208, 212, 216, 220, 224 includes a layer of material that is configured to permit various portions of the semiconductor device 200 (or the layers included therein) to be selectively etched or protected from etching to form one or more of the structures included in the semiconductor device 200.

As further shown in FIG. 2, the semiconductor device 200 includes a plurality of epitaxial (epi) regions 228 that are grown and/or otherwise formed on and/or around portions of the fin structure 204. The epitaxial regions 228 are formed by epitaxial growth. In some implementations, the epitaxial regions 228 are formed in recessed portions in the fin structure 204. The recessed portions may be formed by strained source drain (SSD) etching of the fin structure 204 and/or another type etching operation. The epitaxial regions 228 function as source or drain regions of the transistors included in the semiconductor device 200.

The epitaxial regions 228 are electrically connected to metal source or drain contacts 230 of the transistors included in the semiconductor device 200. The metal source or drain contacts (MDs or CAs) 230 include cobalt (Co), ruthenium (Ru), and/or another conductive or metal material. The transistors further include gates 232 (MGs), which are formed of a polysilicon material, a metal (e.g., tungsten (W) or another metal), and/or another type of conductive material. The metal source or drain contacts 230 and the gates 232 are electrically isolated by one or more sidewall spacers, including spacers 234 in each side of the metal source or drain contacts 230 and spacers 236 on each side of the gate 232. The spacers 234 and 236 include a silicon oxide (SiOₓ), a silicon nitride (SiₓN_{y}), a silicon oxy carbide (SiOC), a silicon oxycarbonitride (SiOCN), and/or another suitable material. In some implementations, the spacers 234 are omitted from the sidewalls of the source or drain contacts 230.

As further shown in FIG. 2, the metal source or drain contacts 230 and the gates 232 are electrically connected to one or more types of interconnects. The interconnects electrically connect the transistors of the semiconductor device 200 and/or electrically connect the transistors to other areas and/or components of the semiconductor device 200. In some implementations, the interconnects electrically connect the transistors to a back end of line (BEOL) region of the semiconductor device 200. In some implementations, the BEOL region may correspond to an interconnect region.

The metal source or drain contacts 230 are electrically connected to source or drain interconnects 238 (e.g., source/drain vias or VDs). One or more of the gates 232 are electrically connected to interconnects 240 (e.g., gate vias or VGs). The interconnects 238 and 240 include a conductive material such as tungsten, cobalt, ruthenium, copper, and/or another type of conductive material. In some implementations, the gates 232 are electrically connected to the interconnects 240 by gate contacts 242 (CB or MP) to reduce contact resistance between the gates 232 and the interconnects 240. The gate contacts 242 include tungsten (W), cobalt (Co), ruthenium (Ru), titanium (Ti), aluminum (Al), copper (Cu) or gold (Au), among other examples of conductive materials.

As further shown in FIG. 2, the interconnects 238 and 240 are electrically connected to a plurality of conductive layers, each including one or more metallization layers and/or vias. As an example, the interconnects 238 and 240 may be electrically connected to an M0 metallization layer that includes conductive structures 244 and 246. The M0 metallization layer is electrically connected to a V0 via layer that includes vias 248 and 250. The V0 via layer is electrically connected to an M1 metallization that includes conductive structures 252 and 254. In some implementations, the conductive layers of the semiconductor device 200 includes additional metallization layers and/or vias that connect the semiconductor device 200 to a package. The BEOL region of the semiconductor device 200 may refer to the region of the semiconductor device 200 above the ESL 208, including the structures/layers 210-226 and 238-254.

As further shown in FIG. 2, the semiconductor device 200 may include one or more devices and/or structures in the BEOL region of the semiconductor device 200. For example, the semiconductor device 200 may include one or more thin film resistor structures 260 in the BEOL region of the semiconductor device 200. The thin film resistor structure 260 may be included in one or more of the dielectric layers 210, 214, 218, 222, and/or 226 in the BEOL region of the semiconductor device 200.

The thin film resistor structure 260 includes a multi-layer resistive body 262. The multi-layer resistive body includes a segment 264 and a segment 266. The segment 264 includes a resistive material. As an example, and in some implementations, the segment 264 includes portion of a layer of a silicon-chromium (SiCr) material. Additionally, or alternatively, the segment 266 corresponds to an oxidized surface region of the segment 264 (e.g., a layer of oxidized silicon-chromium material). In contrast to another multi-layer restive body that might use a combination of materials (e.g., SiCr and tetraethylorhosilicate, or TeOS), the multi-layer resistive body 262 includes a resistive material (e.g., the segment 264 includes SiCr) and an oxidant of the resistive material (e.g., the segment 266 includes an oxidant of SiCr).

The thin film resistor structure 260 further includes a contact structure 268 and a contact structure 270. The contact structures 268 and 270 (e.g., metal landings) are on opposite ends of the segment 264 (e.g., on the silicon-chromium material). The contact structures 268 and 270 may include tungsten (W), cobalt (Co), ruthenium (Ru), titanium (Ti), aluminum (Al), copper (Cu) or gold (Au), among other examples of conductive materials. As shown in FIG. 2, and as a result of using two masking operations as described in greater detail in connection with FIGS. 3B and 3C, segment 266 is on the segment 264 and exclusively between the contact structures 268 and 270.

The thin film resistor structure 260 includes a capping structure 272 and a capping structure 274. The capping structures 272 and 274 are over and/or on the contact structures 268 and 270. As described in greater detail in connection with FIG. 3C and FIG. 3D, the capping structures 272 and 274 may include portions of an anti-reflective coating layer used as part of forming the contact structures 268 and 270. The capping structures 272 and 274 may include a silicon nitride (SiN) material or another suitable material having anti-reflective properties, among other examples.

As shown in FIG. 2, the thin film resistor structure 260 includes an interconnect structure 276 and an interconnect structure 278. The interconnect structures 276 and 278 (e.g., vertical interconnect access structures, or vias) penetrate through the capping structures 272 and 274 to connect with the contact structures 268 and 270. The interconnect structures 276 and 278 may be in the dielectric layer 222 and include tungsten (W), cobalt (Co), ruthenium (Ru), titanium (Ti), aluminum (Al), copper (Cu) or gold (Au), among other examples of conductive materials.

The thin film resistor structure 260 further includes a conductive structure 280 and a conductive structure 282. The conductive structures 280 and 282 connect with the interconnect structures 276 and 278. The conductive structures 280 and 282 may be formed from the same metallization layer used to form the conductive structures 252 and 254 (e.g., the MI metallization layer). In some implementations, the conductive structures 280 and 282 may route to and/or electrically connect with an integrated circuit device in the semiconductor device 200 and form an electrical circuit including the integrated the thin film resistor structure 260.

The thin film resistor structure 260 may be configured to include one or more selected characteristics and/or properties. For example, in some implementations, a sheet resistance (Rₛ) of the multi-layer resistive body 262 is greater than approximately 500 ohms per square (Ω/sq). Selecting the Rₛ to be less than or equal to approximately 500 Ω/sq may cause the thin film resistor structure 260 to fail to satisfy one or more thresholds related to current flow and/or heat generation. Additionally, or alternatively, selecting the Rₛ to be less than or equal to approximately 500 Ω/sq may change a voltage division and/or alter behavior of an electrical circuit including the thin film resistor structure 260 (e.g., an integrated circuit device that is electrically coupled with the thin film resistor structure 260) such that electrical circuit is inoperable within a targeted operating range. Selecting the Rₛ to be greater than approximately 500 ohms per square may cause the thin film resistor structure 260 to satisfy the one or more thresholds and/or enable operability of the electrical circuit within the targeted operating range. However, other values and ranges for the Rₛ of the multi-layer resistive body 262 are within the scope of the present disclosure.

Additionally, or alternatively and as part of the thin film resistor structure 260, a content (e.g., an atomic weight percentage) of silicon in the segment 264 (e.g., a content of silicon in a silicon-chromium layer from which the segment 264 is formed) may be included in a range of approximately 30% to approximately 50%. Selecting the silicon content to be less than approximately 30% may cause the thin film resistor structure 260 to fail to satisfy one or more thresholds related to a resistance value, a thermal coefficient of resistance, and/or a resistivity range. Selecting the silicon content to be between approximately 30% and 50% may satisfy the one or more thresholds and limit instabilities an electrical circuit including the thin film resistor structure 260 (e.g., an integrated circuit device that is electrically coupled with the thin film resistor structure 260) such that the electrical circuit is operable within a targeted operating range. Selecting the silicon content to be greater than approximately 50% may increase instabilities within the electrical circuit to render the electrical circuit inoperable within the targeted operating range. However, other values and ranges for the silicon content of the silicon-chromium material are within the scope of the present disclosure.

Additionally, or alternatively and as part of the thin film resistor structure 260, a magnitude of a thermal coefficient of resistance (TCR) of the multi-layer resistive body 262 (e.g., a magnitude of a positive or negative TCR) may be less than approximately 20 parts per million per degree Celsius (ppm/° C.). Selecting the TCR to be less than approximately 20 ppm/° C. may cause the thin film resistor structure 260 to fail to satisfy one or more thresholds related to temperature compensation. Additionally, or alternatively, selecting the TCR to be less than approximately 20 ppm/° C. may introduce a predictability, a precision, and low error margin for an electrical circuit including the thin film resistor structure 260 (e.g., an integrated circuit device that is electrically coupled with the thin film resistor structure 260) to be operable within a targeted operating range. Selecting the TCR to be greater than or approximately 20 ppm/° C. may render the electrical circuit to be inoperable within the targeted operating range. However, other values and ranges for the TCR of the multi-layer resistive body 262 are within the scope of the present disclosure.

As described in connection with FIG. 2 and elsewhere herein, an implementation of the thin film resistor structure 260 includes a multi-layer resistive body (e.g., the multi-layer resistive body 262) including a layer of a resistive material (e.g., the segment 264) having an oxidized surface region (e.g., the segment 266) between a first end and a second, opposite end of the layer of the resistive material. The thin film resistor structure includes a first contact structure (e.g., the contact structure 268) at the first end of the layer of the resistive material, in direct contact with the resistive material, and adjacent to a first end of the oxidized surface region. The thin film resistor structure includes a second contact structure (the contact structure 270) at the second, opposite end of the layer of the resistive material, in direct contact with the resistive material, and adjacent to a second, opposite end of the oxidized surface region. In some implementations, the oxidized surface region includes an oxidant of the resistive material. Further, and in some implementations, the oxidized surface region is exclusively between the first contact structure and the second contact structure.

Additionally, or alternatively and as described in connection with FIG. 2 and elsewhere herein, a device (e.g., the semiconductor device 200) includes a resistor structure (e.g., the thin film resistor structure 260) within an interconnect region of the device. The resistor structure includes a multi-layer resistive body (e.g., the multi-layer resistive body 262) that includes a layer of a silicon-chromium material (e.g., the segment 264) and a layer of an oxidized silicon-chromium material (e.g., the segment 266) in direct contact with the layer of the silicon-chromium material. The resistor structure includes a contact structure (e.g., the contact structure 268) on a surface of the layer of the silicon-chromium material and adjacent to the layer of the oxidized silicon-chromium material.

As indicated above, FIG. 2 is provided as an example. Other examples may differ from what is described with regard to FIG. 2.

FIGS. 3A-3K are diagrams of an example series of semiconductor manufacturing operations 300 used to form a thin film resistor structure described herein. In some implementations, one or more of the series of semiconductor manufacturing operations 300 may be performed by one or more of the semiconductor processing tools 102-112. In some implementations, one or more of the series of semiconductor manufacturing operations 300 may be performed another semiconductor processing tool.

Turning to FIG. 3A, the series of semiconductor manufacturing operations 300 may be performed in a BEOL region (e.g., an interconnect region) of a semiconductor device (e.g., the semiconductor device 200). For example, a portion of the dielectric layer 222 may be formed over and/or on the ESL 220, and a resistive layer 302 may be formed over and/or on the portion of the dielectric layer 222, among other examples.

The deposition tool 102 may be used to deposit the ESL 220 and/or the portion of the dielectric layer 222 using an epitaxy technique, a CVD technique, a PVD technique, an ALD technique, another deposition technique described above in connection with FIG. 1, and/or a deposition technique other than as described above in connection with FIG. 1. The deposition tool 102 may be used to deposit the resistive layer 302 using an ALD technique, a PVD technique, and/or another technique described above in connection with FIG. 1. In some implementations, the planarization tool 110 may be used to perform a CMP operation to planarize the ESL 220, the portion of the dielectric layer 206, and/or the resistive layer 302.

In FIG. 3B, the deposition tool 102 may be used to deposit a conductive layer 304 on the resistive layer 302 using an epitaxy technique, a CVD technique, a PVD technique, an ALD technique, a plating technique, another deposition technique described above in connection with FIG. 1, and/or a deposition technique other than as described above in connection with FIG. 1. Furthermore, the deposition tool may deposit an anti-reflective coating layer on the conductive layer 304 using an epitaxy technique, a CVD technique, a PVD technique, an ALD technique, another deposition technique described above in connection with FIG. 1, and/or a deposition technique other than as described above in connection with FIG. 1. In some implementations, the planarization tool 110 may be used to perform a CMP operation to planarize the conductive layer 304 and/or the anti-reflective coating layer.

As shown in FIG. 3C, the segment 264 may be formed by removing portions of the resistive layer 302. Furthermore, portions of the conductive layer 304 and the anti-reflective coating layer may be removed. In some implementations, a pattern in a photoresist layer (e.g., a single masking operation) is used to remove the portions of the resistive layer 302, the conductive layer 304, and the anti-reflective coating layer. In these implementations, the deposition tool 102 may be used to form the photoresist layer over and/or on the anti-reflective coating layer. The exposure tool 104 may be used to expose the photoresist layer to a radiation source to pattern the photoresist layer. The developer tool 106 may be used to develop and removes portions of the photoresist layer to expose the pattern. The etch tool 108 may be used to etch portions (e.g., portions not masked by the pattern) of the resistive layer 302, the conductive layer 304, and the anti-reflective coating layer to remove the portions. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique).

Turning to FIG. 3D, the contact structures 268 and 270 may be simultaneously formed by removing portions of the conductive layer 304. Furthermore, the capping structures 272 and 274 may be simultaneously formed by removing portions of the anti-reflective coating layer. In some implementations, a pattern in a photoresist layer (e.g., a single masking operation) is used to remove the portions of the conductive layer 304 and the anti-reflective coating layer. In these implementations, the deposition tool 102 may be used to form the photoresist layer over the anti-reflective coating layer. The exposure tool 104 may be used to expose the photoresist layer to a radiation source to pattern the photoresist layer. The developer tool 106 may be used to develop and removes portions of the photoresist layer to expose the pattern. The etch tool 108 may be used to etch portions (e.g., portions not masked by the pattern) of the anti-reflective coating layer to remove the portions and form the capping structures 272 and 274. Furthermore, the etch tool 108 may be used to etch portions (e.g., portions not masked by the pattern) of the conductive layer 304 to form the contact structures 268 and 270. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique).

As shown in FIG. 3E, the segment 266 (e.g., an oxidized surface region of the segment 264) is formed between the contact structures 268 and 270. In some implementations, a pattern in a photoresist layer is used to mask the dielectric layer 222 and the capping structures 272 and 274 from a wet oxidation process that oxidizes the surface region of the segment 264. In these implementations, the deposition tool 102 may be used to form the photoresist layer over the dielectric layer 222, the segment 264, and the capping structures 272 and 274. The exposure tool 104 may be used to expose the photoresist layer to a radiation source to pattern the photoresist layer. The developer tool 106 may be used to develop and remove portions of the photoresist layer to expose the pattern (e.g., expose a portion of the segment 264 between the contact structures 268 and 270). The etch tool 108 may be used to perform a wet etch process (e.g., a wet oxidation process) using an oxidizing agent that oxidizes a surface of the segment 264 to form the segment 266. Further, and as shown in FIG. 3E, the segment 264 and the segment 266 may combine to form the multi-layer resistive body 262.

In some implementations, and as shown in FIG. 3E, the segment 266 has a thickness of D1. As an example, the thickness D1 may be included in a range of 20 angstroms (Å) to approximately 35 Å. Selecting the thickness D1 to be less than approximately 20 Å may increase a TCR of a thin film resistor structure (e.g., the thin film resistor structure 260) including the multi-layer resistive body 262 and cause the thin film resistor structure to fail to satisfy one or more thresholds related to thermal stability and/or heat dissipation. Additionally, or alternatively, selecting the thickness D1 to be less than approximately 20 Å may change a sensitivity, alter a behavior, and/or limit an operating range of an electrical circuit including the thin film resistor structure (e.g., an integrated circuit device that is electrically coupled with the thin film resistor structure 260) such that the electrical circuit is inoperable within a targeted operating range. Selecting the thickness D1 to be between 20 Å and approximately 35 Å may cause the thin film resistor structure to satisfy the one or more thresholds and/or enable compatibility of the electrical circuit with the available power source. Selecting the thickness DI to be greater than approximately 35 Å may decrease the TCR of the thin film resistor device to fail to satisfy one or more thresholds related to temperature compensation. Additionally, or alternatively, selecting the thickness D1 to be greater than approximately 35 Å may change the sensitivity, alter the behavior, and/or limit the targeted operating range of the electrical circuit such that the electrical circuit is inoperable within the targeted operating range. However, other values and ranges for the thickness D1 are within the scope of the present disclosure.

Further, and as shown in FIG. 3E, the multi-layer resistive body 262 has a thickness of D2. As an example, the thickness D2 may be included in a range of approximately 35 Å to approximately 75 Å. Selecting the thickness D2 to be less than approximately 35 Å may cause the multi-layer resistive body to fail to satisfy one or more thresholds related to an Rₛ. Additionally, or alternatively, selecting the thickness D2 to be less than approximately 35 Å may change a sensitivity, alter a behavior, and/or limit an operating range of an electrical circuit including the thin film resistor structure (e.g., an integrated circuit device that is electrically coupled with the thin film resistor structure 260) such that the electrical circuit is inoperable within a targeted operating range. Selecting the thickness D2 to be between approximately 35 Å and approximately 75 Å may satisfy the one or more thresholds related to the Rₛ and/or enable operability of the electrical circuit within the targeted operating range. Selecting a thickness D2 to be greater than approximately 75 Å may reduce a TCR of the thin film resistor structure and cause the thin film resistor structure to fail to satisfy one or more thresholds related to thermal stability and/or heat dissipation. Additionally, or alternatively, selecting the thickness D2 to be greater than approximately 75 Å may change the sensitivity, alter the behavior, and/or limit a targeted operating range of the electrical circuit such that the electrical circuit is inoperable within the targeted operating range. However, other values and ranges for the thickness D2 are within the scope of the present disclosure.

As shown in FIG. 3F, an additional portion of the dielectric layer 222 may be formed over, on, and/or around the capping structures 272 and 274. The deposition tool 102 may be used to deposit the additional portion of the dielectric layer 222 using an epitaxy technique, a CVD technique, a PVD technique, an ALD technique, another deposition technique described above in connection with FIG. 1, and/or a deposition technique other than as described above in connection with FIG. 1. In some implementations, the planarization tool 110 may be used to perform a CMP operation to planarize the dielectric layer 222 after the additional portion of the dielectric layer 222 is deposited.

As shown in FIG. 3G, recesses 308 and 310 are formed in the dielectric layer 222, through the capping structures 272 and 274, and into the contact structures 268 and 270. In these implementations, the deposition tool 102 may be used to form the photoresist layer over the dielectric layer 222. The exposure tool 104 may be used to expose the photoresist layer to a radiation source to pattern the photoresist layer. The developer tool 106 may be used to develop and removes portions of the photoresist layer to expose the pattern. The etch tool 108 may be used to etch through the dielectric layer 222, through the capping structures 272 and 274, and into portions of the contact structures 268 and 270 to form the recesses 308 and 310. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique).

As shown in FIG. 3H, the recesses 380 and 310 may be filled with one or more conductive materials to respectively form the interconnect structures 276 and 278. The deposition tool 102 and/or the plating tool 112 may deposit the interconnect structures 276 and 278 using a CVD technique, a PVD technique, an ALD technique, an electroplating technique, another deposition technique described above in connection with FIG. 1, and/or a deposition technique other than as described above in connection with FIG. 1. In some implementations, the planarization tool 110 may be used to perform a CMP operation to planarize the interconnect structures 276 and 278.

As shown in FIG. 3I, additional dielectric layers of the BEOL region may be formed. For example, the ESL 224 may be formed over the interconnect structures 276 and 278 and over and/or on the dielectric layer 222. As another example, the dielectric layer 226 may be formed over and/or on the ESL 224. The deposition tool 102 may be used to deposit the ESL 224 and/or the dielectric layer 226 using an epitaxy technique, a CVD technique, a PVD technique, an ALD technique, another deposition technique described above in connection with FIG. 1, and/or a deposition technique other than as described above in connection with FIG. 1. In some implementations, the planarization tool 110 may be used to perform a CMP operation to planarize the ESL 224 and/or the dielectric layer 226 after the ESL 224 and/or the dielectric layer 226 is deposited.

As shown in FIG. 3J, recesses 512 and 514 may be formed through the dielectric layer 226 and through the ESL 224 to expose top surfaces of the interconnect structures 276 and 278. In these implementations, the deposition tool 102 may be used to form the photoresist layer over the dielectric layer 226. The exposure tool 104 may be used to expose the photoresist layer to a radiation source to pattern the photoresist layer. The developer tool 106 may be used to develop and removes portions of the photoresist layer to expose the pattern. The etch tool 108 may be used to etch through the dielectric layer 226 and through the ESL 224 to form the recesses 512 and 514. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique).

As shown in FIG. 3K, the recesses 512 and 514 may be filled with one or more conductive materials to form the conductive structures 280 and 282. The deposition tool 102 and/or the plating tool 112 may deposit the conductive structures 280 and 282 using a CVD technique, a PVD technique, an ALD technique, an electroplating technique, another deposition technique described above in connection with FIG. 1, and/or a deposition technique other than as described above in connection with FIG. 1. In some implementations, the planarization tool 110 may be used to perform a CMP operation to planarize the conductive structures 280 and 282.

As described in connection with FIG. 2 and FIGS. 3A-3K, an amount of semiconductor processing steps to form a thin film resistor structure (e.g., the thin film resistor structure 260) is reduced. Furthermore, a TCR performance and an Rₛ performance of the thin film resistor structure is improved. By reducing the amount of semiconductor processing steps, improving the TCR performance, and improving the Rₛ performance, an amount of resources required to support a market of semiconductor devices using the thin film resistor structure (e.g., semiconductor processing tools, labor, raw material, and/or computing resources) may be reduced relative to other semiconductor devices using other thin film resistor structures formed using other techniques.

As indicated above, FIGS. 3A-3K are provide as an example. Other examples may differ from what is described with regard to FIGS. 3A-3K.

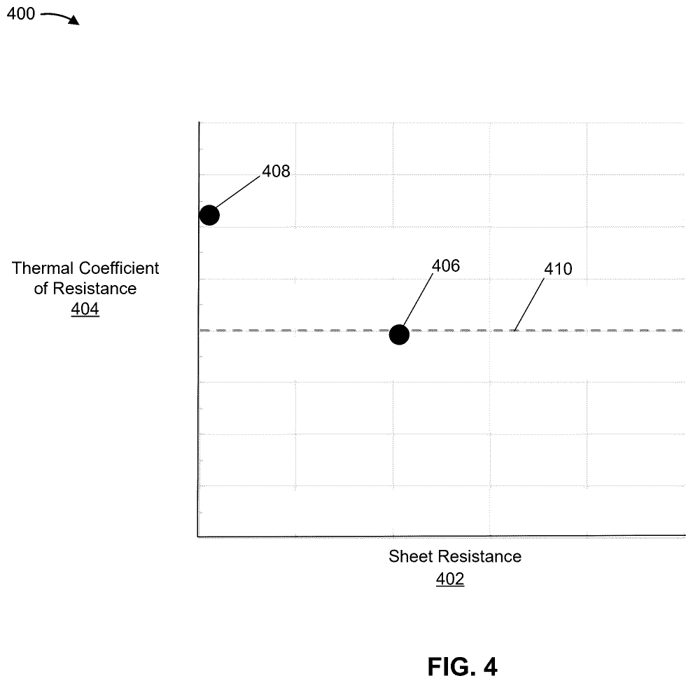

FIG. 4 is a diagram of example data 400 related to a thin film resistor structure described herein. The data 400 illustrates a relationship between Rₛ 402 (e.g., a sheet resistance in (2/sq) and TCR 404 (e.g., a thermal coefficient of resistance in ppm/° C. for a temperature range between approximately 25° C. and 160° C.). The data 400 includes a data point 406 that corresponds to a thin film resistor structure including an oxidized surface region (e.g., the thin film resistor structure 260). The data 400 further includes a data point that 408 corresponds to another think film resistor that excludes an oxidized surface region. Further, and as shown in FIG. 4, reference line 410 may correspond to a TCR of approximately zero ppm/° C.

As shown in FIG. 4, the TCR 404 for the data point 406 (e.g., the thin film resistor structure 260 that includes the oxidized surface region) is approximately zero ppm/° C. Furthermore, the TCR 404 for the data point 408 (e.g., another thin film resistor structure that excludes the oxidized surface region) is greater than the TCR 404 for the data point 406. For example, the TCR 404 for the data point 408 may be approximately 115 ppm/° C. However, other values, ranges, and/or data points associated with TCR 404 are within the scope of the present disclosure.

Additionally, and as shown in FIG. 4, the Rₛ 402 for the data point 406 is greater than the Rₛ 402 for the data point 408. As an example, the Rₛ 402 for the data point 406 may be approximately 700 Ω/sq and the Rₛ 402 for the data point 408 may be approximately 500 Ω/sq. However, other values, ranges, and/or data points associated with Rₛ 402 are within the scope of the present disclosure.

As indicated above, FIG. 4 is provided as an example. Other examples may differ from what is described with regard to FIG. 4.

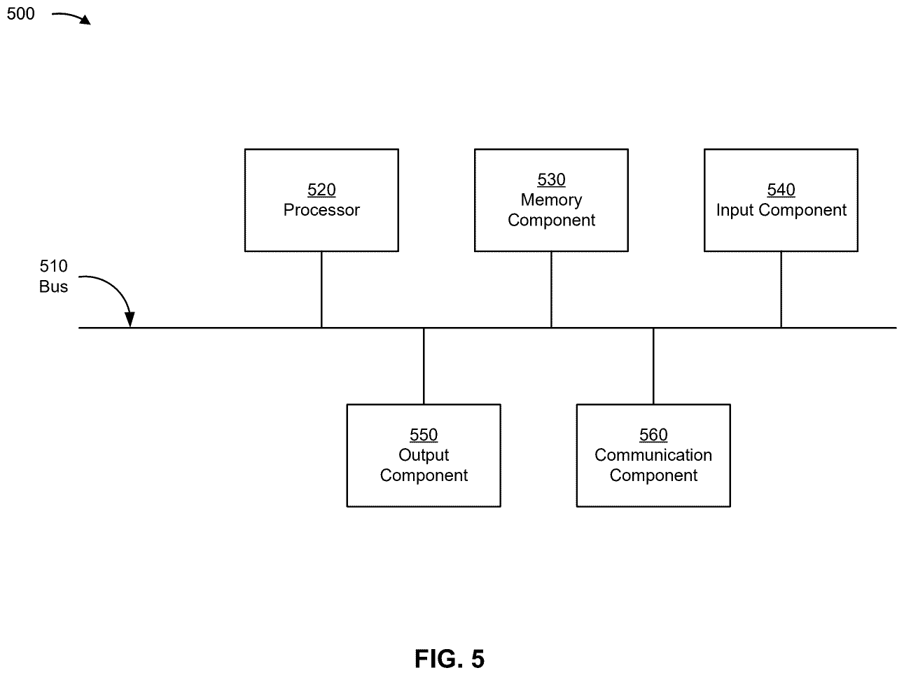

FIG. 5 is a diagram of example components of a device 500 associated with a forming a thin film resistor structure described herein (e.g., the thin film resistor structure 260). In some implementations, one or more of the semiconductor processing tools 102-112 and/or the wafer/die transport tool 114 may include one or more devices 500 and/or one or more components of the device 500. As shown in FIG. 5, the device 500 may include a bus 510, a processor 520, a memory 530, an input component 540, an output component 550, and/or a communication component 560.

The bus 510 may include one or more components that enable wired and/or wireless communication among the components of the device 500. The bus 510 may couple together two or more components of FIG. 5, such as via operative coupling, communicative coupling, electronic coupling, and/or electric coupling. For example, the bus 510 may include an electrical connection (e.g., a wire, a trace, and/or a lead) and/or a wireless bus. The processor 520 may include a central processing unit, a graphics processing unit, a microprocessor, a controller, a microcontroller, a digital signal processor, a field-programmable gate array, an application-specific integrated circuit, and/or another type of processing component. The processor 520 may be implemented in hardware, firmware, or a combination of hardware and software. In some implementations, the processor 520 may include one or more processors capable of being programmed to perform one or more operations or processes described elsewhere herein.

The memory 530 may include volatile and/or nonvolatile memory. For example, the memory 530 may include random access memory (RAM), read only memory (ROM), a hard disk drive, and/or another type of memory (e.g., a flash memory, a magnetic memory, and/or an optical memory). The memory 530 may include internal memory (e.g., RAM, ROM, or a hard disk drive) and/or removable memory (e.g., removable via a universal serial bus connection). The memory 530 may be a non-transitory computer-readable medium. The memory 530 may store information, one or more instructions, and/or software (e.g., one or more software applications) related to the operation of the device 500. In some implementations, the memory 530 may include one or more memories that are coupled (e.g., communicatively coupled) to one or more processors (e.g., processor 520), such as via the bus 510. Communicative coupling between a processor 520 and a memory 530 may enable the processor 520 to read and/or process information stored in the memory 530 and/or to store information in the memory 530.

The input component 540 may enable the device 500 to receive input, such as user input and/or sensed input. For example, the input component 540 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 550 may enable the device 500 to provide output, such as via a display, a speaker, and/or a light-emitting diode. The communication component 560 may enable the device 500 to communicate with other devices via a wired connection and/or a wireless connection. For example, the communication component 560 may include a receiver, a transmitter, a transceiver, a modem, a network interface card, and/or an antenna.

The device 500 may perform one or more operations or processes described herein. For example, a non-transitory computer-readable medium (e.g., memory 530) may store a set of instructions (e.g., one or more instructions or code) for execution by the processor 520. The processor 520 may execute the set of instructions to perform one or more operations or processes described herein. In some implementations, execution of the set of instructions, by one or more processors 520, causes the one or more processors 520 and/or the device 500 to perform one or more operations or processes described herein. In some implementations, hardwired circuitry may be used instead of or in combination with the instructions to perform one or more operations or processes described herein. Additionally, or alternatively, the processor 520 may be configured to perform one or more operations or processes described herein. Thus, implementations described herein are not limited to any specific combination of hardware circuitry and software.

The number and arrangement of components shown in FIG. 5 are provided as an example. The device 500 may include additional components, fewer components, different components, or differently arranged components than those shown in FIG. 5. Additionally, or alternatively, a set of components (e.g., one or more components) of the device 500 may perform one or more functions described as being performed by another set of components of the device 500.

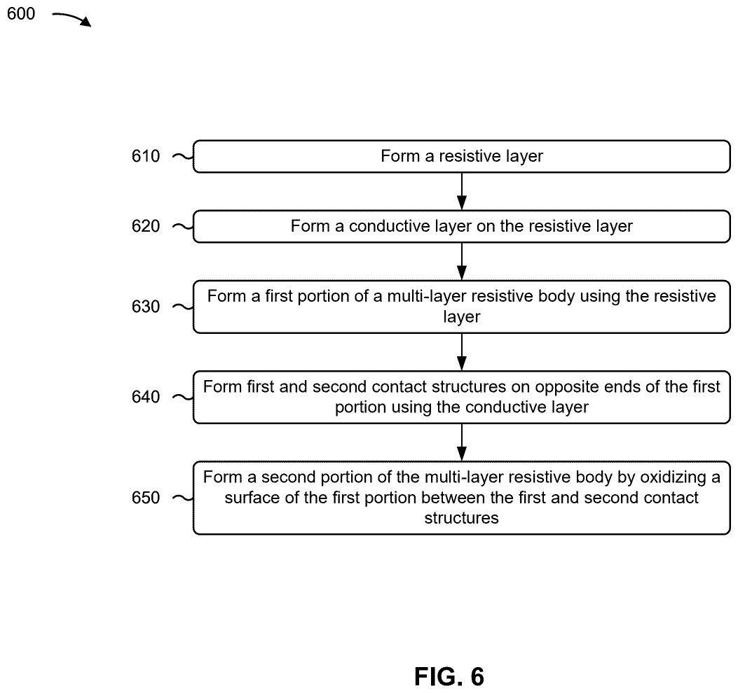

FIG. 6 is a flowchart of an example process 600 associated with forming a thin film resistor structure described herein (e.g., the thin film resistor structure 260). In some implementations, one or more process blocks of FIG. 6 are performed using one or more semiconductor processing tools (e.g., one or more of the semiconductor processing tools 102-112). Additionally, or alternatively, one or more process blocks of FIG. 6 may be performed using one or more components of device 500, such as processor 520, memory 530, input component 540, output component 550, and/or communication component 560.

As shown in FIG. 6, process 600 may include forming a resistive layer (block 610). For example, one or more of the semiconductor processing tools 102-112 may be used to form a resistive layer (e.g., the resistive layer 302), as described herein.

As further shown in FIG. 6, process 600 may include forming a conductive layer on the resistive layer (block 620). For example, one or more of the semiconductor processing tools 102-112 may be used to form a conductive layer (e.g., the conductive layer 304) on the resistive layer, as described herein.

As further shown in FIG. 6, process 600 may include forming a first portion of a multi-layer resistive body using the resistive layer (block 630). For example, one or more of the semiconductor processing tools 102-112 may be used to form a first portion (e.g., the segment 264) using the resistive layer, as described herein.

As further shown in FIG. 6, process 600 may include forming first and second contact structures on opposite ends of the first portion using the conductive layer (block 640). For example, one or more of the semiconductor processing tools 102-112 may be used to form first and second contact structures (e.g., the contact structures 268 and 270) on opposite ends of the first portion using the conductive layer, as described herein.

As further shown in FIG. 6, process 600 may include forming a second portion of the multi-layer resistive body by oxidizing a surface of the first portion between the first and second contact structures (block 650). For example, one or more of the semiconductor processing tools 102-112 may be used to form a second portion (e.g., the segment 264) of the multi-layer resistive body by oxidizing a surface of the first portion between the first and second contact structures, as described herein.

Process 600 may include additional implementations, such as any single implementation or any combination of implementations described below and/or in connection with one or more other processes described elsewhere herein.

In a first implementation, forming the resistive layer (e.g., the resistive layer 302) includes forming a layer of a silicon-chromium material.

In a second implementation, alone or in combination with the first implementation, forming the layer of the silicon-chromium material includes forming the layer of the silicon-chromium material using a dual component physical vapor deposition process.

In a third implementation, alone or in combination with one or more of the first and second implementations, oxidizing the surface of the first portion (e.g., the segment 264) includes using a wet oxidation process to oxidize the silicon-chromium material.

In a fourth implementation, alone or in combination with one or more of the first through third implementations, forming the first portion (e.g., the segment 264) and the first and second contact structures (e.g., the contact structures 268 and 270) includes forming the first portion and the first and second contact structures using a total of two masking operations.

In a fifth implementation, alone or in combination with one or more of the first through fourth implementations, using the total of two masking operations includes using a first masking operation to define the first portion (e.g., the segment 264), and using a second masking operation to simultaneously define the first and second contact structures (e.g., the contact structures 268 and 270).

In a sixth implementation, alone or in combination with one or more of the first through fifth implementations, process 600 includes forming a dielectric layer (e.g., the dielectric layer 222) over the first and second contact structures (e.g., the contact structures 268 and 270), and forming interconnect structures (e.g., the interconnect structures 276 and 278) through the dielectric layer (e.g., the dielectric layer 222) to the first and second contact structures.

In a seventh implementation, alone or in combination with one or more of the first through sixth implementations, process 600 includes forming an anti-reflective coating layer (e.g., the anti-reflective coating layer 306) on the conductive layer (e.g., the conductive layer 304) prior to forming the first and second contact structures (e.g., the contact structures 268 and 270).

In an eighth implementation, alone or in combination with one or more of the first through seventh implementations, forming the first and second contact structures (e.g., the contact structures 268 and 270) includes removing unmasked portions of the anti-reflective coating layer (e.g., the anti-reflective coating layer 306) and the conductive layer (e.g., the conductive layer 304).

In a ninth implementation, alone or in combination with one or more of the first through eighth implementations, process 600 includes forming a dielectric region (e.g., the dielectric layer 222) over remaining portions of the anti-reflective coating layer (e.g., the capping structures 272 and 274), and forming interconnect structures (e.g., the interconnect structures 276 and 278) through the dielectric region, through the remaining portions of the anti-reflective coating layer, and to the first and second contact structures (e.g., the contact structures 268 and 270).

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

Some implementations described herein include a semiconductor device including a thin film resistor structure and techniques for forming the thin film resistor structure. Techniques described herein include forming a layer of a resistive material using a dual-component physical vapor deposition process and forming contact structures on the layer of resistive material by directly patterning a layer of conductive material on the layer of the resistive material. The techniques further include oxidizing a surface of the layer of the resistive material between the contact structures.

In this way, an amount of semiconductor processing steps to form the thin film resistor structure is reduced. Furthermore, a TCR performance and an Rₛ performance of the thin film resistor structure is improved. By reducing the amount of semiconductor processing steps, improving the TCR performance, and improving the Rₛ performance, an amount of resources required to support a market of semiconductor devices using the thin film resistor structure (e.g., semiconductor processing tools, labor, raw material, and/or computing resources) may be reduced relative to other semiconductor devices using other thin film resistor structures formed using other techniques.

As described in greater detail above, some implementations described herein provide a structure. The structure includes a multi-layer resistive body including a layer of a resistive material having an oxidized surface region between a first end and a second, opposite end of the layer of the resistive material. The structure includes a first contact structure at the first end of the layer of the resistive material, in direct contact with the resistive material, and adjacent to a first end of the oxidized surface region. The structure includes a second contact structure at the second, opposite end of the layer of the resistive material, in direct contact with the resistive material, and adjacent to a second, opposite end of the oxidized surface region.

As described in greater detail above, some implementations described herein provide a method. The method includes forming a resistive layer. The method includes forming a conductive layer on the resistive layer. The method includes forming a first portion of a multi-layer resistive body using the resistive layer. The method includes forming first and second contact structures on opposite ends of the first portion using the conductive layer. The method includes forming a second portion of the multi-layer resistive body by oxidizing a surface of the first portion between the first and second contact structures.

As described in greater detail above, some implementations described herein provide a structure. The structure includes a multi-layer resistive body including a layer of a resistive material having an oxidized surface region between a first end and a second, opposite end of the layer of the resistive material. The structure includes a first contact structure at the first end of the layer of the resistive material, in direct contact with the resistive material, and adjacent to a first end of the oxidized surface region. The structure includes a second contact structure at the second, opposite end of the layer of the resistive material, in direct contact with the resistive material, and adjacent to a second, opposite end of the oxidized surface region. In some implementations, the oxidized surface region includes an oxidant of the resistive material. Further, and in some implementations, the oxidized surface region is exclusively between the first contact structure and the second contact structure.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a multi-layer resistive body including a layer of a resistive material having an oxidized surface region between a first end and a second, opposite end of the layer of the resistive material;
a first contact structure at the first end of the layer of the resistive material, in direct contact with the resistive material, and adjacent to a first end of the oxidized surface region; and
a second contact structure at the second, opposite end of the layer of the resistive material, in direct contact with the resistive material, and adjacent to a second, opposite end of the oxidized surface region,
wherein the oxidized surface region includes an oxidant of the resistive material, and
wherein the oxidized surface region is exclusively between the first contact structure and the second contact structure.

2. The structure of claim 1, wherein the layer of the resistive material comprises:
a silicon-chromium material.

3. The structure of claim 1, wherein a sheet resistance of the multi-layer resistive body is greater than approximately 500 ohms per square.

4. The structure of claim 1, wherein a thickness of the oxidized surface region is included in a range of approximately 20 angstroms to approximately 35 angstroms.

5. The structure of claim 1, wherein a thickness of the multi-layer resistive body is included in a range of approximately 35 angstroms to approximately 75 angstroms.

6. A device, comprising:
a resistor structure within an interconnect region of the device, comprising:
a multi-layer resistive body, comprising:
a layer of a silicon-chromium material; and
a layer of an oxidized silicon-chromium material in direct contact with the layer of the silicon-chromium material; and
a contact structure on a surface of the layer of the silicon-chromium material and adjacent to the layer of the oxidized silicon-chromium material.

7. The device of claim 6, wherein the contact structure comprises:
a surface that is in direct contact with the surface of the layer of the silicon-chromium material.

8. The device of claim 6, further comprising:
a capping structure on the contact structure, and
an interconnect structure that penetrates through the capping structure to the contact structure.

9. The device of claim 6, wherein a magnitude of a thermal coefficient of resistance of the multi-layer resistive body is less than approximately 20 parts per million per degree Celsius.

10. The device of claim 6, wherein a content of silicon in the silicon-chromium material is included in a range of approximately 30% to approximately 50%.

11. A method, comprising:
forming a resistive layer;
forming a conductive layer on the resistive layer;
forming a first portion of a multi-layer resistive body using the resistive layer;
forming first and second contact structures on opposite ends of the first portion using the conductive layer; and
forming a second portion of the multi-layer resistive body by oxidizing a surface of the first portion between the first and second contact structures.

12. The method of claim 11, wherein forming the resistive layer includes:
forming a layer of a silicon-chromium material.

13. The method of claim 12, wherein forming the layer of the silicon-chromium material includes:
forming the layer of the silicon-chromium material using a dual component physical vapor deposition process.

14. The method of claim 12, wherein oxidizing the surface of the first portion includes:
using a wet oxidation process to oxidize the silicon-chromium material.

15. The method of claim 11, wherein forming the first portion and the first and second contact structures includes:
forming the first portion and the first and second contact structures using a total of two masking operations.

16. The method of claim 15, wherein using the total of two masking operations includes:
using a first masking operation to define the first portion; and
using a second masking operation to simultaneously define the first and second contact structures.

17. The method of claim 11, further including:
forming a dielectric region over the first and second contact structures, and
forming interconnect structures through the dielectric region to the first and second contact structures.

18. The method of claim 11, further including:
forming an anti-reflective coating layer on the conductive layer prior to forming the first and second contact structures.

19. The method of claim 18, wherein forming the first and second contact structures includes:
removing unmasked portions of the anti-reflective coating layer and the conductive layer.

20. The method of claim 19, further including:
forming a dielectric region over remaining portions of the anti-reflective coating layer, and
forming interconnect structures through the dielectric region, through the remaining portions of the anti-reflective coating layer, and to the first and second contact structures.
